(19) United States
(12) Patent Application Publication
(10) Pub. No.: US 2010/0186994 A1
(43) Pub. Date: Jul. 29, 2010

(54) IMPROVEMENTS IN AND RELATING TO MANUFACTURE OF ELECTRICAL CIRCUITS FOR ELECTRICAL COMPONENTS

(75) Inventors: Paul Westmarland, Anglesey (GB); Daniel Bamford, Anglesey (GB)

Correspondence Address: DeMont & Breyer, LLC, 100 Commons Way, Ste. 250, Holmdel, NJ, 07733, US

(73) Assignee: DEEPSTREAM TECHNOLOGIES LTD., Gwynedd (GB)

(21) Appl. No.: 12/669,163

(22) PCT Filed: Jul. 16, 2008
(86) PCT No.: PCT/GB08/02419

§ 371 Date: Apr. 9, 2010

(30) Foreign Application Priority Data
Jul. 18, 2007 (GB) 0714034.6

(51) Int. Cl. H05K 3/00; H05K 1/00

(52) U.S. Cl. 174/250; 264/160; 29/829; 216/13

(57) ABSTRACT

A method of forming an electrical circuit for an electrical component comprises the steps of; producing an electrical circuit from a planar conductive material, the circuit including tracks and tie bars between tracks; over-moulding the electrical circuit ith plastics material leaving tie bars in apertures; and removing the tie bars after the over-moulding process.

### FIELD OF THE INVENTION

This invention concerns improvements in and relating to the manufacture of electrical circuits for electrical components.

### BACKGROUND OF THE INVENTION

The shape and functionality of electrical devices such as, for example, circuit breakers, residual current devices, ground fault interrupters and arc fault interrupters, has remained unchanged for years. Within the electrical switchgear and circuit protection and monitoring industries there is an increasing drive and desire to reduce the size of electrical devices and to integrate more functionality into the devices.

Increasing the functionality of such electrical devices typically involves integration of electronic components. However, for known electrical devices, this leads to the problem of insufficient internal surface area to accommodate additional printed circuit boards, or other similar substrates, required to enable the increased functionality, while maintaining the external size of the device.

In our co-pending application we propose over-moulding stamped or etched electrical circuits in plastics material. There is, however, a need to provide support for such circuits during the moulding process.

### SUMMARY OF THE INVENTION

An object of the present invention is to provide a method of manufacturing electrical circuits for electrical components in which the electrical circuits are over-moulded with plastics material.

According to the invention there is provided a method of forming an electrical circuit for an electrical component comprising the steps of:
a) producing an electrical circuit from a planar conductive material, the circuit including tracks and tie bars between tracks;
b) over-moulding the electrical circuit with plastics material leaving tie bars in apertures; and
c) removing the tie bars after the over-moulding process.

The present invention further provides an electrical circuit for an electrical component manufactured by the steps of:
a) producing an electrical circuit from a planar conductive material, the circuit including tracks and tie bars between tracks;
b) over-moulding the electrical circuit with plastics material leaving tie bars in apertures; and
c) removing the tie bars after the over-moulding process.

The electrical circuit may be formed in any suitable way but typically will be formed by stamping or etching the planar conductive material. Planar sheet copper alloy is preferably used for the electrical circuit.

Over-moulding is preferably carried out in a mould having formations that mate with tie bar locations to form apertures around the tie bars in the over-moulded electrical circuit. Preferably such a mould formation will comprise a platform and raised portions that locate either side of a tie bar. Preferably the raised portions of the mould formation a tight fit between the tie bar and connected tracks, in order to prevent flashing or leakage of plastics material.

The tie bars are preferably removed by laser cutting, although a fluid jet or mechanical punching could be used. Laser cutting of the tie bars may be carried out as a single shot process or may be by cutting the tie bars at opposite track edges to form a slug that drops away. Preferably tie bar material is removed during or after laser cutting by blown gas or by suction. The laser cutting operation is preferably microprocessor controlled.

After removal of the tie bars a second overmoulding process is preferably carried out and this overmoulding preferably fills gaps created by removal of tie bars.

Where the electrical circuit has multiple tracks alongside each other it is preferred that tie bars be staggered, so that inaccurate removal of tie bars is less likely to cause loss of integrity of tracks and or impair track to track isolation characteristics, especially for high voltage tracks.

The spacing between adjacent tracks is advantageously greater adjacent the tie bars.

### BRIEF DESCRIPTION OF THE DRAWINGS

This invention will now be described, by way of example only, with reference to the accompanying drawings, in which:

FIG. 1 shows a typical lead frame for an electrical component;

FIG. 2 shows the lead frame of FIG. 1 over-moulded with tie bar apertures;

FIG. 3 shows tie bar detail:

FIG. 4 shows mould tool detail for forming tie bars;

FIG. 5 shows a preferred tie bar configuration;

FIG. 6 shows worst case cutting of tie bars of a FIG. 5 type tie bar configuration;

FIG. 7 shows worst case cutting of tie bars of an alternative tie bar configuration; and

FIGS. 8 and 9 show a tie bar geometry wherein the spacing between adjacent tracks is greater adjacent the tie bars.

### DETAILED DESCRIPTION

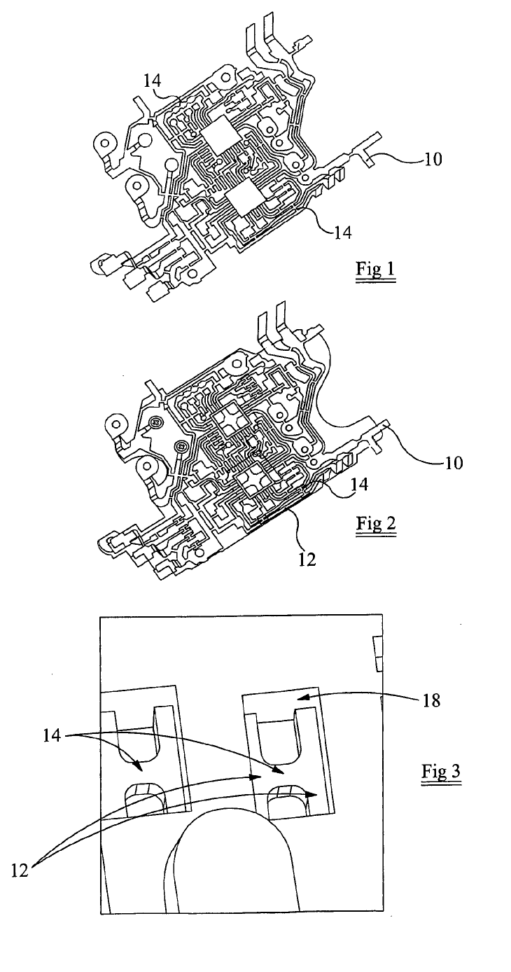

Referring to the accompanying drawings, in order to create an electrical circuit for an electrical component a lead frame 10 is formed from a planar sheet of copper alloy by stamping or chemical etching. The lead frame includes various tracks 12 and tie bars 14 holding tracks together for over-moulding with plastics material 16 to create an over-moulded lead frame as shown in FIG. 2 of the drawings.

The tie bars 14 are provided to support the tracks and hold the lead frame together during the over-moulding process. Thereafter the tie bars are removed by laser cutting and the over-moulded component can be further over-moulded to provide desirable surface features, such as location formations for other over-moulded lead—frames. The additional overmould also forms an effective electrical isolation barrier allowing high voltage circuits to be placed in close proximity to one another whilst maintaining a high breakdown voltage, typically in the order of 4 Kv @ 1 mm separation.

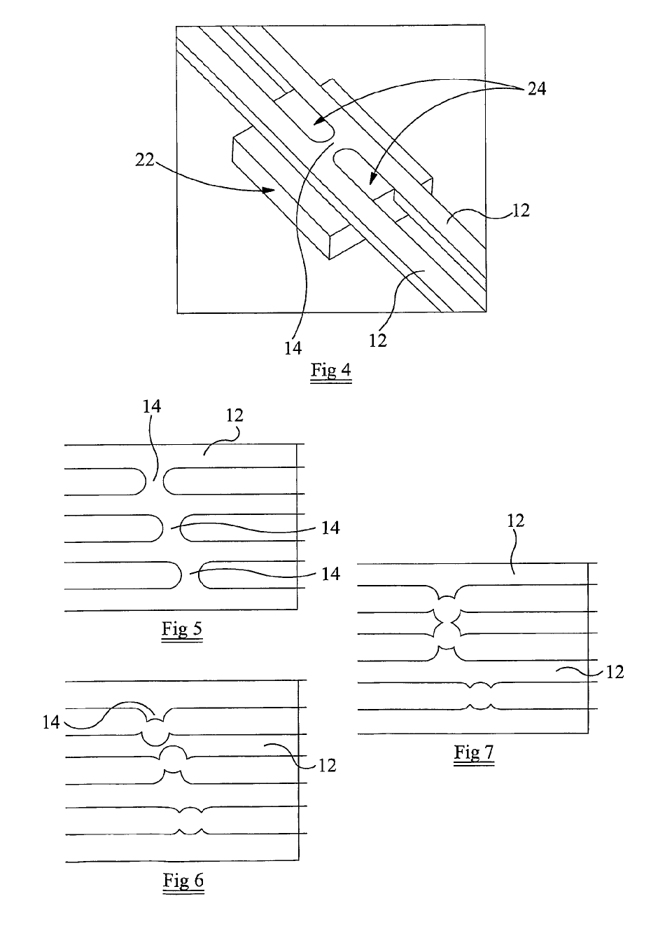

In order to form the tie bars 14 the over-moulding has to leave space around the tie bars, so that the laser cutting does not damage the plastics material in over-mould burning or melting Therefore, as shown in FIG. 3 the plastics material is moulded so as to leave apertures 18 around the tie bars 14. To achieve this the mould (FIG. 4) for the over-moulding process incorporates platforms 22 with castellations 24 that locate between tracks 12 either side of a tie bar 14. Such a mould creates the apertures 18 around the tie bars as shown in FIG. 3. A close fit between castellation 24, tie bar 14 and track 12 is needed in order to prevent flashing or leakage of plastics material.

After over-moulding the tie bars need to be cut and laser cutting is preferred to burn away the tie bars. However, cutting of the tie bars may alternatively be carried out using a fluid jet—either a gas or liquid. When using a laser the aperture around a tie bar is needed to reduce or eliminate burning of plastics material surrounding the tie bar. Mechanical punching to remove tie bars is a possible alternative to laser or fluid jet cutting but mechanical punches are relatively expensive and difficult to manufacture at the sizes required, would be prone to damage from use and would transmit undesirable mechanical stress to the surrounding over-mould and track. Additionally, circuit density, track and gap width would have to be less than for a circuit prepared using laser or fluid jet cutting and tie bar apertures would need to be larger to accommodate a suitably sized punch and die block.

Advantageously using laser or fluid jet cutting allows a non-dedicated tool to be used for different track layouts and no mechanical force is imparted to the lead frame. Mechanical punching may deform or delaminate tracks from the overmoulding. The laser cutting or fluid jet process is controlled by a microprocessor, which can be reprogrammed according to the electrical circuit design.

Laser or fluid jet cutting may be carried out as a single shot, wherein the tie bar is removed in its entirety. Alternatively, a cut line method may be used, wherein two lines are cut at the track edges allowing the remaining slug of the tie bar to fall away. The aperture around the tie bar means that the molten tie bar material or the tie bar slug are not captured in the surrounding plastics material.

The tie bar size is important for providing sufficient support to its adjacent tracks as well as allowing effective removal thereof. The preferred track width to track gap ratio is between about 1.68:1 and 1:1, especially between 1.68:1 and 1.5:1. A typical circuit example has a tie bar width of 0.30 mm and track spacing of 0.42 mm. In order to remove the tie bar effectively by laser, the laser has to have a spot size of 0.40 mm in diameter. The minimum aperture gap either side of the tie bar area to be cut is 0.40 mm, whilst the minimum aperture width is the track spacing plus 2½ times the half track width. This gives an effective minimum aperture size of 1.22 mm×0.80 mm. The aperture formed by the moulding itself is undrafted, due to the relative thinness of the over-mould.

After removal of the tie bars a second overmoulding typically of an engineering thermoplastic, resin or encapsulent, is carried out in order to fill the gaps created by removal of the tie bars.

FIGS. 5 to 7 illustrate other factors to be taken into account when siting tie bars between multiple track arrangements. In these circumstances desirably tie bars between adjacent pairs of tracks sited close together are staggered relative to each other as shown in FIG. 5. FIG. 6 shows the effect of laser removal of tie bars when the laser cuts are misplaced so that they cut up to 50% into the tracks. As can be seen the integrity of each track is maintained. However, as shown in FIG. 7 with non-staggered tie bars misplaced laser cutting up to 50% into the tracks can lead to a very thin section of track remaining or complete loss of track integrity rendering the circuit useless.

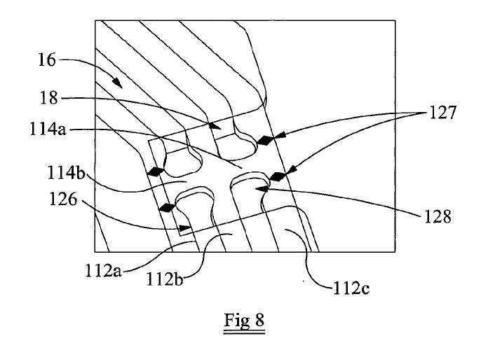

FIG. 8 shows a preferred embodiment wherein the tracks, 112a, 112b and 112c are joined by tie bars, 114a and 114b, and separated by a space 126 extending parallel with adjacent tracks between tie bars. In this region the dimension of the space 126 between adjacent tracks is less than approximately 0.4 mm. In the region of the tie bars 114 the dimension of the space 126 between adjacent tracks is greater and the track width is reduced to a minimum of about 0.25 mm (127) thereby forming an enlarged space 128.

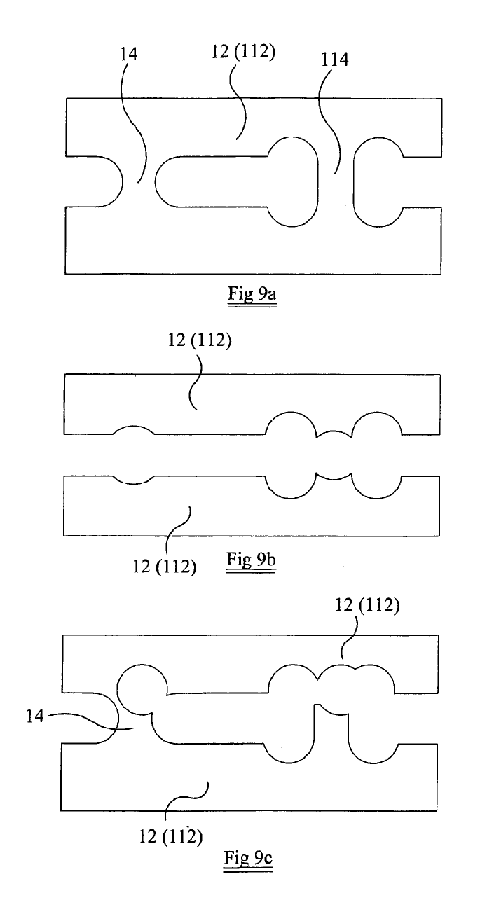

FIG. 9 shows the preferred embodiment, of FIG. 8, wherein the track spacing is increased and the track width decreased adjacent the tie bar.

FIG. 9a shows tracks 112 and tie bars 114 having geometry as shown in FIG. 8 compared to the track 12 and tie bar 14 on the left as previously described, with reference to FIGS. 4 to 7.

FIG. 9b shows how an accurately executed cut removes the tie bars 14 and 114, of both the previously described track and tie bar configuration, of FIGS. 4 to 7, and the profiled track and tie bar configuration of FIG. 8.

FIG. 9c shows how an inaccurately executed cut fails to successfully remove the tie bar 14 of the previously described track 12 and tie bar 14 configuration, of FIGS. 4 to 7, but successfully removes the tie bar 114 of the profiled track 114 and tie bar 112 configuration of FIG. 8.

The preferred embodiment of FIGS. 8 and 9 therefore provides a significant advantage in that it is more tolerant of the manufacturing process.

1. A method of forming an electrical circuit for an electrical component comprising the steps of:
(a) producing an electrical circuit from a planar conductive material, the circuit including tracks and tie bars between tracks;
(b) over-moulding the electrical circuit with plastics material leaving tie bars in apertures; and
(c) removing the tie bars after the over-moulding process.

2. The method as claimed in claim 1, wherein the electrical circuit is formed by stamping the planar conductive material.

3. The method as claimed in claim 1, wherein the electrical circuit is formed by etching the planar conductive material.

4. The method as claimed in claim 1, wherein the planar conductive material is planar sheet copper alloy.

5. The method as claimed in claim 1, wherein over-moulding is carried out in a mould having formations that mate with tie bar locations to form apertures around the tie bars in the over-moulded electrical circuit.

6. The method as claimed in claim 5, wherein the mould formation comprises a platform and raised portions that locate either side of a tie bar.

7. The method as claimed in claim 6, wherein the raised portions of the mould formation are a tight fit between the tie bar and connected tracks.

8. The method as claimed in claim 1, wherein the tie bars are removed by laser cutting.

9. The method as claimed in claim 1, wherein the tie bars are cut by a jet of fluid.

10. The method as claimed in claim 8, wherein the removal of the tie bars is carried out as a single shot process.

11. The method as claimed in claim 8, wherein the removal of the tie bars is carried out by cutting the tie bars at opposite track edges to form a slug that drops away.

12. The method as claimed in claim 8, wherein tie bar material is removed after cutting by blown gas or by suction.

13. The method as claimed in claim 1, wherein the tie bar removal step is controlled by a microprocessor.

14. The method as claimed in claim 1, wherein, where the electrical circuit has multiple tracks alongside each other, the tie bars are staggered.

15. The method as claimed in claim 1 wherein the spacing between adjacent tracks is greater adjacent the tie bars.

16. The method as claimed in claim 1 comprising a second over-moulding step after removal of the tie bars.

17. The electrical circuit for an electrical component made by a method as claimed in claim 1.
